(19) United States
(12) Patent Application Publication
(10) Pub. No.: US 2011/0133853 A1
(43) Pub. Date: Jun. 9, 2011

(54) SEMICONDUCTOR DEVICE WITH FILTER CIRCUIT

(75) Inventors: Fumio HARIMA, Kanagawa (JP); Koichi Hasegawa, Kanagawa (JP)

(73) Assignee: RENESAS ELECTRONICS CORPORATION

(21) Appl. No.: 12/959,910

(22) Filed: Dec. 3, 2010

(30) Foreign Application Priority Data
Dec. 4, 2009 (JP) 2009-276848

(51) Int. Cl. H03H 7/01

(52) U.S. Cl. 333/175; 333/185

(57) ABSTRACT

A filter circuit formed on a semiconductor chip, includes an input node provided to input an input signal; an output bonding pad provided to output an output signal; a ground bonding pad provided to be connected a ground through a bonding wire; a parallel resonant circuit provided between the input node and the output bonding pad and having one end connected to the output bonding pad; and a serial resonant circuit having one end which is provided between the input node and the other end of the parallel resonant circuit and the other end connected with the ground bonding pad. The serial resonant circuit includes a capacitor and an inductor which are connected in serial, and the parallel resonant circuit includes a capacitor and an inductor which are connected in parallel.

### INCORPORATION BY REFERENCE

This patent application claims a priority on convention based on Japanese Patent Application No. 2009-276848. The disclosure thereof is incorporated herein by reference.

### TECHNICAL FIELD

The present invention relates to a semiconductor device, and especially, to a semiconductor device which has a built-in filter circuit.

### BACKGROUND ART

In radio communication by use of a mobile phone, an available frequency band is assigned on the basis of application and unnecessary radiation and the leakage of power outside the band are regulated. In a radio transmitter, a harmonic signal generated from a power amplifier becomes a problem. Therefore, the harmonic signal is generally removed by use of various filter circuits such as an LPF (Low Pass Filter) and a BPF (Band Pass Filter).

The filter circuit is often mounted as a part separate from the power amplifier. For example, the filter circuit is configured from chip inductors and chip capacitors which are individual parts, or the filter circuit is configured from a single multi-layer ceramic part in which the above parts are integrated. There is sometimes a case that the filter circuit is configured from a SAW (Surface Acoustic Wave) filter which uses piezoelectric elements as parts.

On the other hand, a request to a mobile terminal of a small size is increasing in recent years, and the reduction of the number of parts and integration of the parts are carried out. The filter circuit is mounted in the form of an IPD (Integrated Passive Device) in which spiral inductors and capacitors of the filter circuit are formed on a semiconductor chip through a semiconductor process and a MMIC (Monolithic Microwave Integrated Circuits) in which the filter circuit is formed on a same semiconductor chip as an active device.

When the filter circuit is formed on a semiconductor chip, the spiral inductors and MIM (Metal-Insulator-Metal) capacitors are used as passive elements on the semiconductor chip. When a ground terminal GND is necessary, a ground terminal is connected with a ground pad in a package for the semiconductor chip, by use of a bonding wire and a through-hole provided for the semiconductor chip.

If the ground pad is shared when the filter circuit is integrated in a single semiconductor chip and in the package, a problem is caused that the signal transmission characteristics of the filter circuit degrade so that a rejection quantity of a harmonic signal decreases. The problem is pronounced when an amplifier and the filter circuit are integrated.

FIG. 1A is a top view of a mount substrate 1, and FIG. 1B is a cross sectional view of the mount substrate 1 along the line A-B in FIG. 1A. FIG. 1C is a top view of a semiconductor package 2 which contains a semiconductor chip with a filter circuit. The semiconductor package 2 is mounted on the mount substrate 1.

The mount substrate 1 is provided with a package mounted area 11, a surface metal ground pattern 12, surface metal patterns 13 for signals, a mount substrate material plate 14, a plurality of through-hole electrodes 15 and a back metal ground pattern 16. The surface metal ground pattern 12 is arranged in a central portion on the front surface of the mount substrate 1. The signal surface metal patterns 13 are isolated from the surface metal ground pattern 12 and are arranged around the surface metal ground pattern 12. The semiconductor chip 20 is provided with a filter circuit 21 with a plurality of bonding pads 26b, 26c, and 26d. The semiconductor package 2 is provided with mold resin 22, the semiconductor chip 20 mounted on a mount portion 23, an a plurality of pins 24 including a filter circuit output pin 24d, and a plurality of bonding wires 25b, 25c, and 25d.

In the mount substrate 1, the plurality of through-holes 15 pass through the mount substrate material plate 14. One end of each of the through-holes 15 is connected with the surface metal ground pattern 12. The other end of each through-hole 15 is connected with the back metal ground pattern 16.

In the Semiconductor package 2, one ends of the plurality of bonding wires 25b to 25d are connected with the plurality of bonding pads 26b to 26d of the filter circuit 21 on the semiconductor chip 20, respectively. Also, the other ends of the plurality of bonding wires 25b and 25c are connected with the mount portion 23, and the other end of the bonding wire 25d is connected with the filter circuit output pin 24d.

The semiconductor chip 20 is mounted on the mount portion 23. The mount portion 23 in which semiconductor chip 20 is mounted, and the plurality of pins 24 are made as pins of a metal lead frame and they are fixed with the mold resin 22.

The semiconductor package 2 is mounted in the package mounted area 11 of the mount substrate 1. The mount portion 23 of the semiconductor package 2 and the plurality of pins 24 are connected with the surface metal ground pattern 12 and the signal surface metal patterns 13 in the mount substrate 1, respectively.

FIG. 2 is an equivalent circuit diagram showing the configuration of the filter circuit 21 on the semiconductor chip 20 in the conventional semiconductor package 2 in consideration of parasitic components. The equivalent circuit is provided with a filter circuit input node 29, the first to third bonding wires 25b to 25d, the first to third bonding pads 26b to 26d, the filter circuit output pin 24d, first to fifth inductors L1 to L5, first to third capacitors C1 to C3, a first path 27, and second and third paths 28b and 28c.

The mount portion 23 to which the bonding wires 25b and 25c are connected is not an ideal ground terminal GND. In actual, a connection path between each of the bonding wires 25b and 25c and the ground terminal GND is through the surface metal ground patterns 12 and the through-holes 15 in the mount substrate 1. Therefore, each of the second and third paths 28b and 28c corresponding to these paths has a parasitic inductance. On the other hand, the path 27 which connects the bonding wire 25b and the bonding wire 25c through the mount portion 23 also has a parasitic inductance.

It should be noted that in a case of a conventional example, a relation of (length of path 27)<<(lengths of paths 28b and 28c) is met. Because the parasitic inductances of the paths 27, 28b, and 28c are approximately proportional to the lengths, a relation of (the parasitic inductance of the path 27) >> (the parasitic inductances of the paths 28b and 28c) is met. It should be noted that the parasitic inductances of the paths 28b and 28c are sufficiently small as compared with the inductors L1 to L5 in the filter circuit, so that the parasitic inductances of the paths 28b and 28c can be regarded as L_GND. Similarly, the parasitic inductance of the path 27 can be regarded as L_ISO.

The connection relation of the components in

FIG. 2 will be described. A filter circuit input node 29 is connected with one end of a fourth inductor L4. The other end of the fourth inductor L4 is connected with one end of a third inductor L3, one end of a first capacitor C1 and one end of a third capacitor C3. The other end of the first capacitor C1 is connected with one end of a first inductor L1. The other end of the first inductor L1 is connected with a first bonding pad 26b and one end of a first bonding wire 25b. The other end of the first bonding wire 25b is connected with one end of the first path 27 and one end of the second path 28b. The other end of the second path 28b is grounded. The other end of the third inductor L3 is connected with the other end of the third capacitor C3, one end of a second capacitor C2, and one end of a fifth inductor L5. The other end of the second capacitor C2 is connected with one end of a second inductor L2. The other end of the second inductor L2 is connected with a second bonding pad 26c and one end of a second bonding wire 25c. The other end of the second bonding wire 25c is connected with the other end of the first path 27 and one end in a third path 28c. The other end of the third path 28c is grounded. The other end of the fifth inductor L5 is connected with a third bonding pad 26d and one end of a third bonding wire 25d. The other end of the third bonding wire 25d is connected with the filter circuit output pin 24d.

The first and second capacitors C1 and C2 are connected with the first and second inductors L1 and L2 in serial, and operate as first and second serial resonant circuits, respectively. These two resonant circuits are grounded through the first and second bonding wires 25b and 25c and the second and third paths 28b and 28c, respectively. These two resonant circuits pass specific frequency components such as harmonic components to be attenuated to the ground. As a result, the filter circuit 21 attenuates or removes (rejects) the specific frequency components such as the harmonic components from a signal inputted from filter circuit input node 29, to output a resultant signal to the filter circuit output pin 24d.

The third capacitor C3 is connected with the third inductor L3 to operate as a first parallel resonant circuit. The resonant circuit is serially connected with the filter circuit input node 29 through the fourth inductor L4 and is serially connected with the filter circuit output pin 24d through the fifth inductor L5. The resonant circuit prevents a specific frequency component such as a harmonic component to be attenuated from passing through. As a result, the filter circuit 21 attenuates the specific frequency component such as the harmonic component, from the signal inputted from the filter circuit input node 29, to output the attenuated signal to the filter circuit output pin 24d.

FIG. 3 shows a graph of a simulation result of signal transmission characteristics of a semiconductor device with a conventional filter circuit. When the fundamental frequency (f0) of an input signal is set to 2.45 GHz, the signal transmission characteristics (S21) of the filter circuit are shown which prevents (rejects) a 4.9-GHz component as a second-order harmonic frequency signal (2f0). In this graph, the horizontal axis shows the frequency of an input signal to the filter circuit and the vertical axis shows the signal transmission characteristics of the filter circuit.

In this graph, a first curve S(2,1) shows the signal transmission characteristics of the filter circuit in an ideal grounding condition in which the parasitic inductances L_GND and L_ISO can be ignored. A rejection quantity of 2f0 in this case is shown by a marker ml as a ratio of a passage signal to the input signal. A Second curve S(4,3) shows a characteristic of the conventional filter circuit which contains the parasitic inductances and the rejection quantity of 2f0 is shown by a marker m2.

In conjunction with the above description, Japanese Patent Publication (JP-A-Heisei 2-34014) as Patent Literature 1 discloses a composite semiconductor device. In the composite semiconductor device, passive devices for a matching circuit of an amplifier are formed as MMIC on an identical semiconductor chip. However, because an on-chip spiral inductor has a bad Q-value, attention should be paid on a loss in a filter circuit.

Also, Patent Literature 2 (Japanese Patent Publication JP 2002-93845) discloses a technique of an integrated signal filter circuit. The integrated signal filter circuit is configured from passive elements on a semiconductor chip. In the integrated signal filter circuit, a spiral inductor is replaced with a wire inductance to improve a Q-value.

However, when active devices such as an amplifier are mounted on an identical semiconductor chip, or mounted on an identical package even if it is another chip, propagation of a signal through a ground pad causes a problem often since the ground pad is shared.

Patent Literature 3 (International Publication W02003/094232) discloses a semiconductor device. In the semiconductor device, the ground pad is separated in a package in order to prevent a low frequency noise from propagating through the ground pad.

### Citation List:

[Patent Literature 1]: JP-A-Heisei 2-34014

[Patent Literature 2]: JP 2002-93845A

[Patent Literature 3]: W02003/094232

### SUMMARY OF THE INVENTION

As shown in FIG. 3, in the semiconductor device which contains the conventional filter circuit, the rejection quantity of 2f0 becomes little in a case of the marker m2 in which the parasitic inductances are contained, compared with a case of the marker m1 in which the parasitic inductances are ignored.

This is because the mount portion 23 to which the bonding wires 25b and 25c are connected is not the ideal ground, but parts mounted onto a substrate such as a package are grounded through the through-holes so that parasitic inductances L_GND are added. The isolation is degraded when the parasitic inductances L_GND become sufficiently larger than the parasitic inductance L ISO between the bonding wires 25b and 25c, so that a harmonic frequency component rejected by the first serial resonant circuit is outputted to the filter circuit output pin 24d through the second serial resonant circuit and the mount portion 23. Also, since the third parallel resonant circuit which prevents a harmonic frequency component is bypassed by passing through the first second serial resonant circuits, the rejection quantity becomes little in any resonant circuit.

Also, in the semiconductor device containing the conventional filter circuit, the rejection quantity of the frequency of 2f0 becomes little when the parasitic inductance is contained, but a pole where the rejection quantity is −50 dB at maximum is present at 5.7 GHz. When a frequency to the pole is shifted by containing the parasitic inductance, the rejection quantity of the frequency of 2f0 can be made maximum through optimal designing.

However, the parasitic inductances of the paths 27, 28b, and 28c vary depending on not the semiconductor device in the package but the length and diameter of each of the through-holes 15 formed in the mount substrate 1. Therefore, when the optimization should be carried out including the parasitic inductances, the rejection quantity of the filter circuit, too, is changed if the pattern of the mount substrate is different.

In an aspect of the present invention, a filter circuit formed on a semiconductor chip, includes an input node provided to input an input signal; an output bonding pad provided to output an output signal; a ground bonding pad provided to be connected a ground through a bonding wire; a parallel resonant circuit provided between the input node and the output bonding pad and having one end connected to the output bonding pad; and a serial resonant circuit having one end which is provided between the input node and the other end of the parallel resonant circuit and the other end connected with the ground bonding pad. The serial resonant circuit includes a capacitor and an inductor which are connected in serial, and the parallel resonant circuit includes a capacitor and an inductor which are connected in parallel.

In another aspect of the present invention, a semiconductor package includes: a semiconductor chip on which a filter circuit is configured; a mount portion on which the semiconductor chip is mounted and which is designed to be connected with the ground bonding pad through the bonding wire; and a filter circuit output pin designed to be connected with the output bonding pad through a bonding wire. The filter circuit includes: an input node provided to input an input signal; an output bonding pad provided to output an output signal; a ground bonding pad provided to be connected a ground through a bonding wire; a parallel resonant circuit provided between the input node and the output bonding pad and having one end connected to the output bonding pad; and a serial resonant circuit having one end which is provided between the input node and the other end of the parallel resonant circuit and the other end connected with the ground bonding pad. The serial resonant circuit includes a capacitor and an inductor which are connected in serial, and the parallel resonant circuit includes a capacitor and an inductor which are connected in parallel.

In a still another aspect of the present invention, a semiconductor device includes: a mount substrate; and a semiconductor package designed to be mounted on the mount substrate. The semiconductor package includes: a semiconductor chip on which a filter circuit is configured; a mount portion on which the semiconductor chip is mounted and which is designed to be connected with the ground bonding pad through the bonding wire; and a filter circuit output pin designed to be connected with the output bonding pad through a bonding wire. The filter circuit includes: an input node provided to input an input signal; an output bonding pad provided to output an output signal; a ground bonding pad provided to be connected a ground through a bonding wire; a parallel resonant circuit provided between the input node and the output bonding pad and having one end connected to the output bonding pad; and a serial resonant circuit having one end which is provided between the input node and the other end of the parallel resonant circuit and the other end connected with the ground bonding pad. The serial resonant circuit includes a capacitor and an inductor which are connected in serial, and the parallel resonant circuit includes a capacitor and an inductor which are connected in parallel. The mount substrate includes: a surface metal ground pattern designed to be connected with the mount portion; front metal patterns for signals designed to be connected with the filter circuit input node and the filter circuit output pin; a back metal ground pattern designed to be connected with the surface metal ground pattern; and a connection section configured to connect the surface metal ground pattern and the back metal ground pattern.

According to the semiconductor device of the present invention, the harmonic frequency component propagating back through the ground can be prevented by providing a band rejection filter circuit of a parallel resonant type on the side of a package output of the filter circuit.

### BRIEF DESCRIPTION OF THE DRAWINGS

The above and other objects, advantages and features of the present invention will be more apparent from the following description of certain embodiments taken in conjunction with the accompanying drawings, in which:

FIG. 1A is a top view of a mount substrate on which a semiconductor chip is mounted;

FIG. 1B is a cross sectional view of the mount substrate along the line A-B in FIG. 1A;

FIG. 1C is a top view of a semiconductor package which contains the semiconductor chip with a conventional filter circuit;

FIG. 2 is an equivalent circuit diagram showing a configuration of the conventional filter circuit on the semiconductor chip on a semiconductor package in consideration of parasitic components;

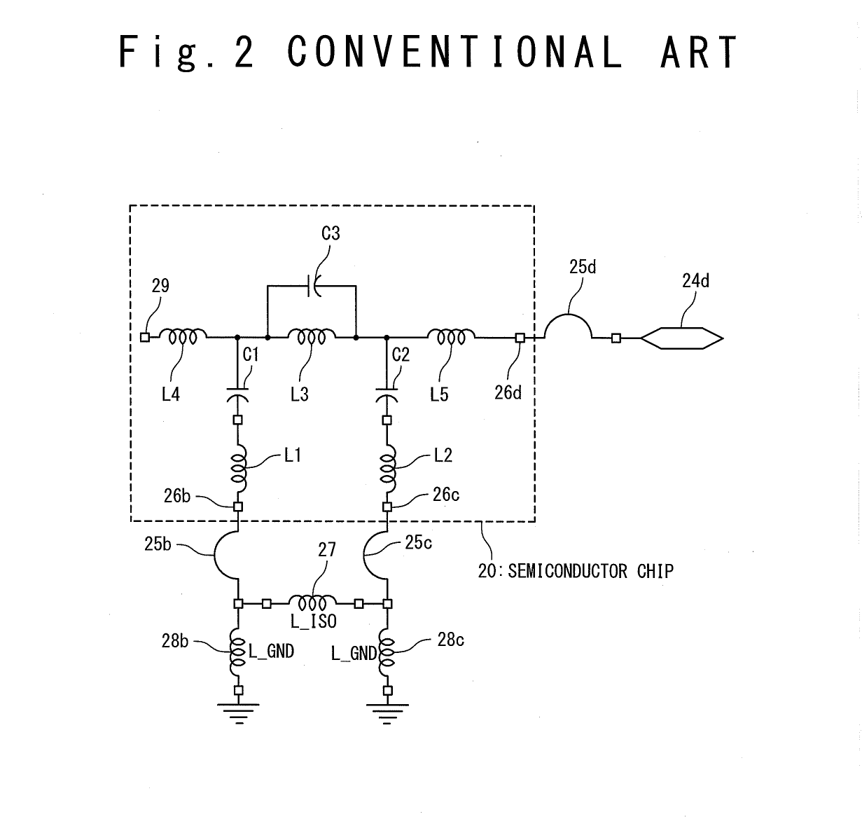

FIG. 3 shows a graph of a simulation result of signal transmission characteristics of a semiconductor device with a conventional filter circuit;

FIG. 4 is an equivalent circuit diagram showing the configuration of a filter circuit formed on the semiconductor device according to a first embodiment of the present invention;

FIG. 5 is an equivalent circuit diagram showing the configuration of the filter circuit of the semiconductor device with according to a second embodiment of the present invention;

FIG. 6 is an equivalent circuit diagram showing the configuration of the filter circuit of the semiconductor device according to a third embodiment of the present invention; and

FIG. 7 is a table showing simulation results of rejection quantities of a second-order harmonic frequency component (2f0) in the signal transmission characteristics of the filter circuit according to the present invention.

### DESCRIPTION OF THE EMBODIMENTS

Hereinafter, a semiconductor device of the present invention will be described with reference to the attached drawings.

### First Embodiment

The semiconductor device according to a first embodiment of the present invention will be described.

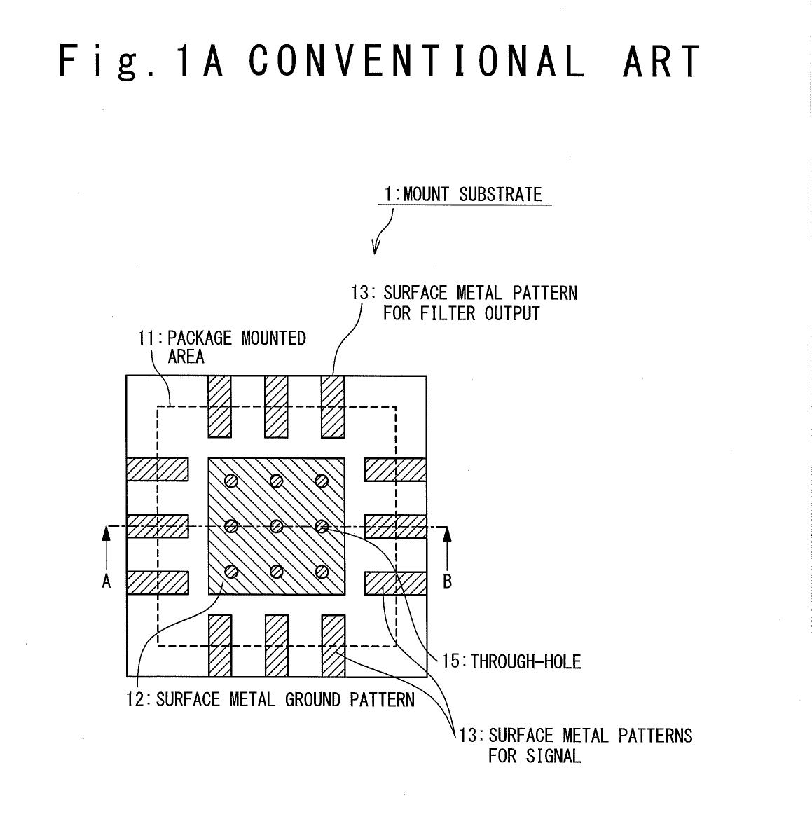

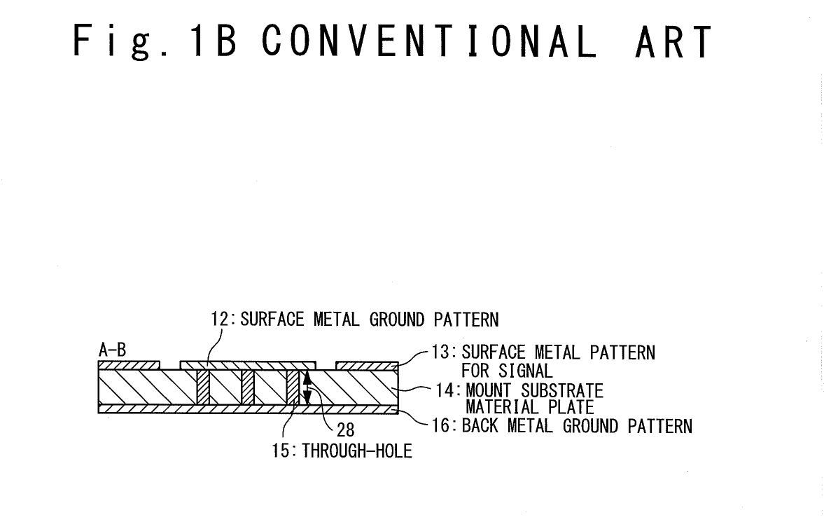

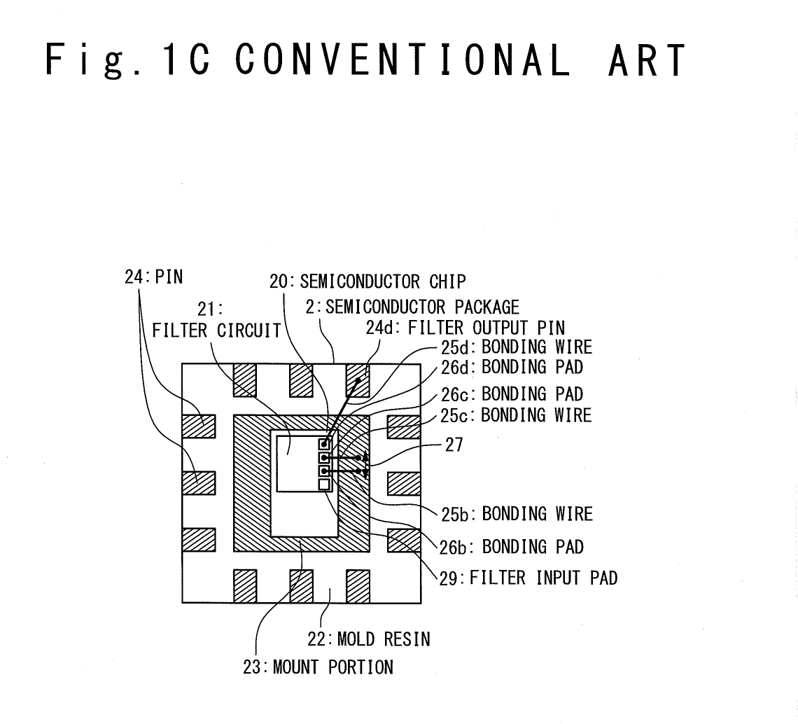

The overall configuration of the semiconductor device according to the present embodiment of the present invention is similar to the semiconductor device described with reference to FIGS. 1A to 1C.

In the mount substrate 1, the plurality of through-holes 15 pass through the mount substrate material plate 14. One end of each of the through-holes 15 is connected with the surface metal ground pattern 12, and the other end of the through-hole 15 is connected with the back metal ground pattern 16.

In the semiconductor package 2, one ends of the plurality of bonding wires 25b to 25d are connected with the plurality of bonding pads 26b to 26d of the filter circuit 21 formed on the semiconductor chip 20, respectively. Also, the other ends of the plurality of bonding wires 25b and 25c are connected with the mount portion 23. The other end of the bonding wire 25d is connected with the filter circuit output pin 24d.

The semiconductor chip 20 is mounted on the mount portion 23. The mount portion 23 where the semiconductor chip 20 is mounted, and the plurality of pins 24 and 24b are fixed by the mold resin 22.

The semiconductor package 2 is mounted on the package mounted area 11 of the mount substrate 1. The mount portion 23 of the semiconductor package 2 and the plurality of pins 24 and 24b are connected with the surface metal ground pattern 12 of the mount substrate 1 and the signal surface metal patterns 13, respectively.

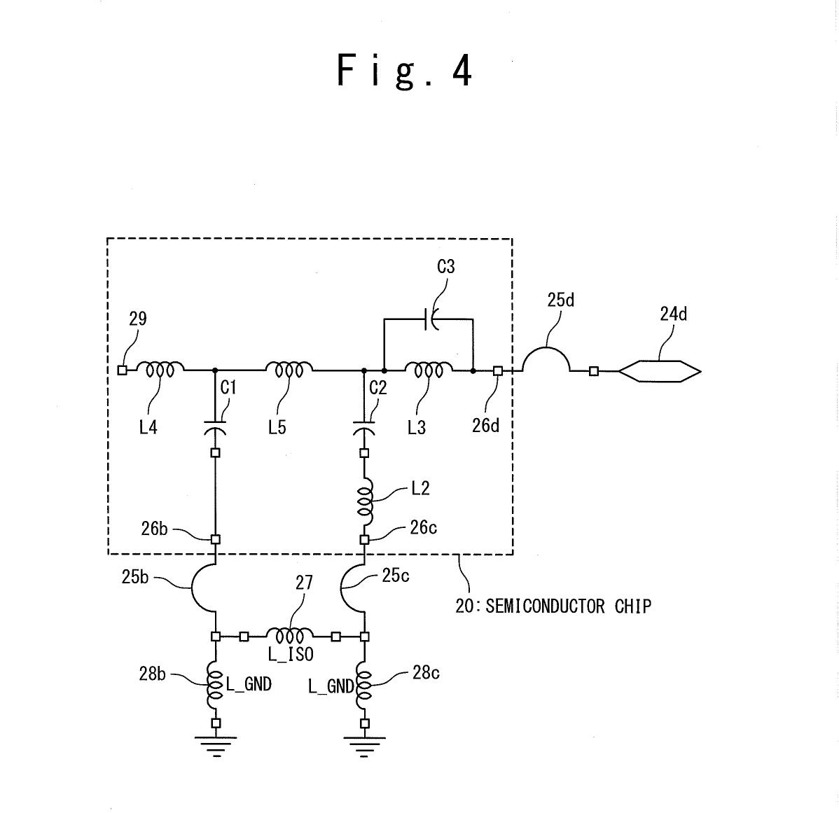

FIG. 4 is an equivalent circuit diagram showing the configuration of the filter circuit 21 formed on the semiconductor chip 20 of the semiconductor device according to the first embodiment of the present invention in consideration to the parasitic components. The circuit diagram of the filter circuit in the first embodiment is different from that of the conventional semiconductor device. The equivalent circuit in the first embodiment is provided with the first to third bonding wires 25b to 25d, the first to third bonding pads 26b to 26d, the filter circuit output pin 24d, the filter circuit input node 29, the second to fifth inductors L2 to L5, the first to third capacitors C1 to C3, the first path 27, the second path 28b, and the third path 28c.

The mount portion 23 to which the bonding wires 25b and 25c are connected is not the ideal ground. In actual, the connection between each of the bonding wires 25b and 25c and the ground passes through the surface metal ground pattern 12 and through-hole electrode 15 in the mount substrate 1. Therefore, each of the second and third paths 28b and 28c has a parasitic inductance. On the other hand, the path 27 which connects between the bonding wire 25b and the bonding wire 25c through the mount portion 23 has a parasitic inductance. It should be noted that a relation of (the length of path 27)<<(the lengths of paths 28b and 28c) is met, in a case of the present embodiment. Also, because the parasitic inductances of the paths 27, 28b, 28c are approximately proportional to the lengths, a relation of (the parasitic inductance of path 27)<<(the parasitic inductances of the paths 28b and 28c) is met. It should be noted that the parasitic inductances of the paths 28b and 28c are sufficiently small compared with the inductances of the inductors L2 to L5 in the filter circuit, so that the parasitic inductances of the paths 28b and 28c can be regarded as L_GND, respectively, and the parasitic inductance of the path 27 can be regarded as L_ISO.

The connection relation of the components shown in FIG. 4 will be described. The filter circuit input node 29 is connected with one end of the fourth inductor L4. The other end of the fourth inductor L4 is connected with one end of the fifth inductor L5 and one end of the first capacitor C1. The other end of the first capacitor C1 is connected with the first bonding pad 26b and one end of the first bonding wire 25b. The other end of the first bonding wire 25b is connected with one end of the first path 27 and one end of the second path 28b. The other end of the second path 28b is grounded. The other end of the fifth inductor L5 is connected with one end of the second capacitor C2, one end of the third capacitor C3 and one end of the third inductor L3. The other end of the second capacitor C2 is connected with one end of the second inductor L2. The other end of the second inductor L2 is connected with the second bonding pad 26c and one end of the second bonding wire 25c. The other end of the second bonding wire 25c is connected with the other end of the first path 27 and one end of the third path 28c. The other end of the third path 28c is grounded. The other end of the third inductor L3 is connected with the other end of the third capacitance C3, the third bonding pad 26d and one end of the third bonding wire 25d. The other end of the third bonding wire 25d is connected with the filter circuit output pin 24d.

The second capacitor C2 is connected with the second inductor L2 to operate as the serial resonant circuit. The resonant circuit is grounded through the bonding wire 25c and the path 28c. This resonant circuit passes a specific frequency component such as a harmonic frequency component to be attenuated, to connect to the ground. As a result, the filter circuit 21 removes (rejects) the specific frequency component such as the harmonic frequency component from the signal inputted to the filter circuit input node 29, and an attenuation resultant signal is outputted to the filter circuit output pin 24d.

The third capacitor C3 is connected with the third inductor L3 in parallel to operate as a first parallel resonant circuit. The resonant circuit is connected in serial with the fifth inductor L5 through the fourth inductor L4 and the filter circuit input node 29 and is connected in serial with the filter circuit output pin 24d. The resonant circuit prevents the specific frequency component such as the harmonic frequency component from passing without attenuation. As a result, the filter circuit 21 attenuates the specific frequency component such as the harmonic component from the signal inputted from filter circuit input node 29, and a resultant signal is outputted to the filter circuit output pin 24d.

Here, the plurality of bonding wires 25b and 25c in FIG. 4 correspond to the plurality of bonding wires 25b and 25c in FIGS. 1A to 1C which connect the semiconductor chip 20 and the mount portion 23. The parasitic inductance L ISO of the first path 27 in FIG. 4 corresponds to the path 27 on the mount portion 23 in FIGS. 1A to 1C. The parasitic inductances L_GND of the second and third paths 28b and 28c in FIG. 4 correspond to the plurality of through-holes 15 in FIGS. 1A to 1C. The ground to which the second and third paths 28b and 28c in FIG. 4 are connected corresponds to the back metal ground pattern 16 in FIGS. 1A to 1C. Besides, the components which correspond to the plurality of capacitors C1 to C3 and inductors L2 to L5 in FIG. 4 are built in the semiconductor chip 20 in FIGS. 1A to 1C.

It should be noted that the filter circuit output pin 24d is a signal output section of the semiconductor package. Therefore, the first parallel resonant circuit is arranged in a position to be connected with the signal output section of the semiconductor package, on the signal path in the filter circuit of the present embodiment, and only the first parallel resonant circuit is connected in serial with the filter circuit output pin 24d.

As shown in FIGS. 1A to 1C and described above, in the semiconductor device of the present embodiment, because the through-hole 15 has an inductance, the surface metal ground pattern 12 and the lead frame (a mount area) mounted on the pattern 12 are connected with the back metal ground pattern 16 through the parasitic inductance.

Also, the parasitic inductances L_ISO are generated between the ground wires in the filter circuit which shares the surface metal ground pattern 12 and the lead frame (the mount area) mounted on the pattern 12.

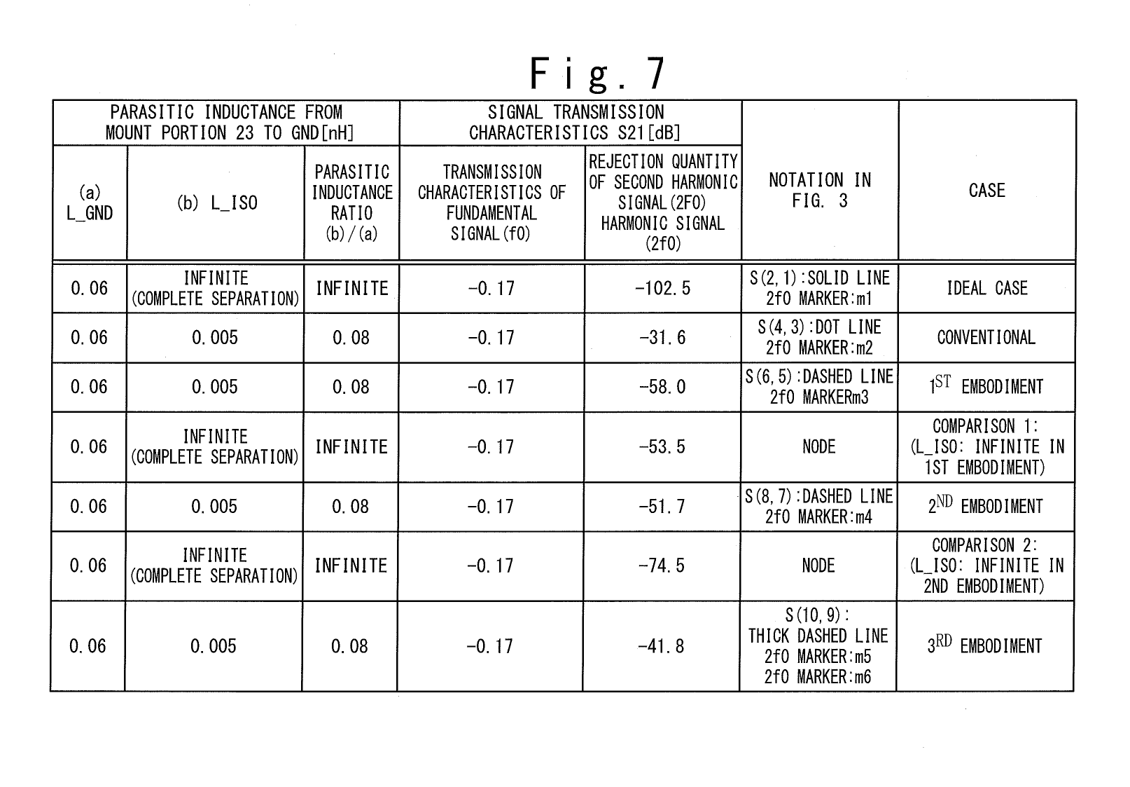

A table of FIG. 7 shows the simulation results of a rejection quantity of the second-order harmonic frequency component (2f0) in the signal transmission characteristics of the filter circuit according to the present invention. The change of the signal transmission characteristics is shown in according to the change of the parasitic inductance from the mount portion 23 as an origin point to which the bonding wires 25b and 25c are connected, to the back metal ground pattern 16 through the path 27, 28b and 28c.

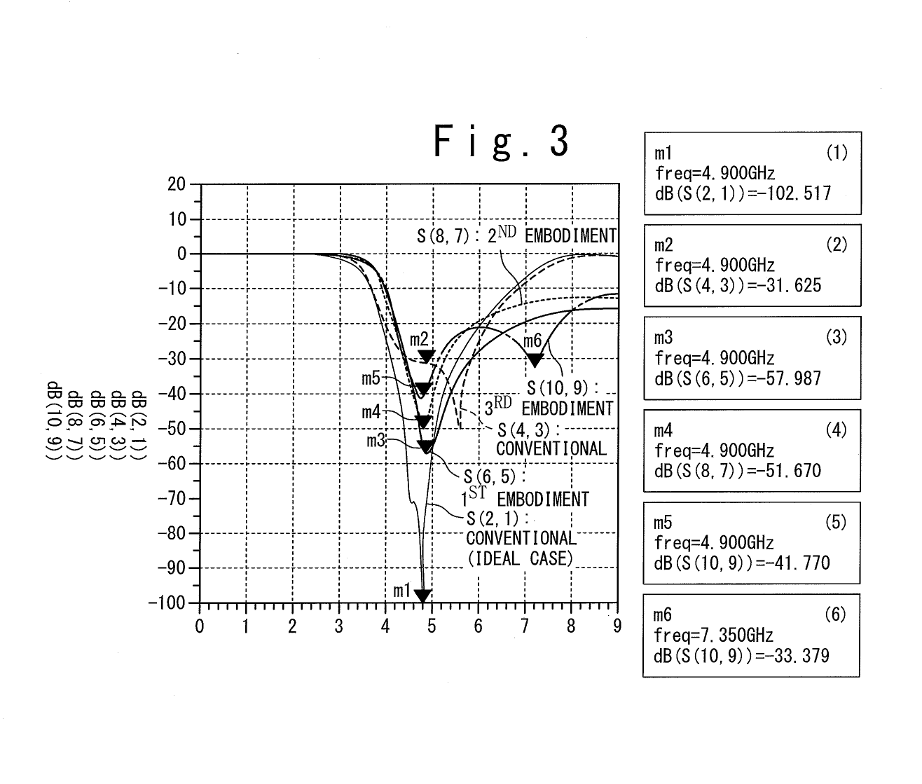

FIG. 3 is the graph showing the simulation results of the signal transmission characteristics in the filter circuits of the semiconductor devices. FIG. 3 shows the signal transmission characteristics (S21) of the filter circuit in which the fundamental frequency component (f0) of the input signal is set to be 2.45 GHz, and prevents (rejects) 4.9 GHz as the second-order harmonic frequency component (2f0). In the graph, the horizontal axis is the frequency of the input signal to the filter circuit and the vertical axis is the signal transmission characteristics of the filter circuit. Four curves in FIG. 3 correspond to from S(2,1) to S(10,9) in the column of “notion in FIG. 3” in table, respectively. The rejection quantity of the frequency component 2f0 is shown by the marker m1 to m6 as ratios of the passage signal to the input signal, and as the value becomes smaller, the rejection quantity becomes larger.

The parasitic inductances L_GND in the paths 28b and 28c vary in accordance with conditions such as a condition of the through-holes. The electromagnetic field simulation result is shown as L GND in the table of FIG. 7 when the substrate thickness is 0.2 mm, the radius of the through-hole is 0.2 mm, and the plating thickness is 17 μm. In the electromagnetic field simulation result, the inductance of each through-hole electrode is 0.06 nH. Therefore, in the table of FIG. 7, the inductance is noted as L_GND=0.06 nH and the parasitic inductance L_ISO in the path 27 is shown as a ratio to L_GND.

In the filter circuit, the sufficient rejection quantity is obtained in a case of the ideal value in which the parasitic inductance is not contained, i.e. in a case of the marker ml in which L_GND/L_ISO is infinite, but the rejection quantity decreases in a case of presence of the parasitic inductance and the marker m2 in which L_GND/L_ISO becomes 0.08.

In the conventional example, the harmonic frequency component rejected by the first serial resonant circuit propagates to the filter circuit output terminal through the second serial resonant circuit, because the parasitic inductance L_GND becomes sufficiently larger than L_ISO so that the isolation between the first serial resonant circuit and the second serial resonant circuit is degraded. Also, the harmonic frequency component passes through the first and second serial resonant circuits, to bypass the third parallel resonant circuit for blocking the harmonic frequency component, so that the first and second serial resonant circuits function as a signal path for the harmonic frequency component to return to the signal line. In this way, the rejection quantity becomes little at any resonant circuit.

In the first embodiment of the present invention shown in FIG. 4, the first parallel resonant circuit operates as a part of the filter circuit to block the harmonic frequency component. In the present invention, a band blocking filter of a this parallel resonant type is arranged in the output section of the semiconductor device, to block the harmonic frequency component propagating back from the ground through the serial resonant circuit as a grounding element. By this configuration, in the semiconductor device of the present invention, the rejection quantity of the harmonic frequency component can be secured regardless of the parasitic inductance to degrade the ground connection performance of the surface metal ground pattern 12 and the lead frame (the mount area) mounted on the pattern 12.

Also, in case of the conventional example, the rejection quantity is influenced by the parasitic inductance, and the frequency at which the rejection quantity is maximum is shifted from the frequency of 2f0 due to the parasitic inductance. In the first embodiment of the present invention, the resonant frequency for 2f0 by the first parallel resonant circuit is determined. Because the resonant frequency does not depend on the parasitic inductances L_GND and L_ISO, the resonant frequency is not influenced by the parasitic inductances.

In the first embodiment of the present invention, the rejection quantity of 2f0 is −58.0 dB in the marker m3 in which the ratio of the parasitic inductances L_GND/L ISO is 0.08, and the rejection quantity increases by 26.4 dB, as compared with the conventional example in which contains the parasitic inductances.

### Second Embodiment

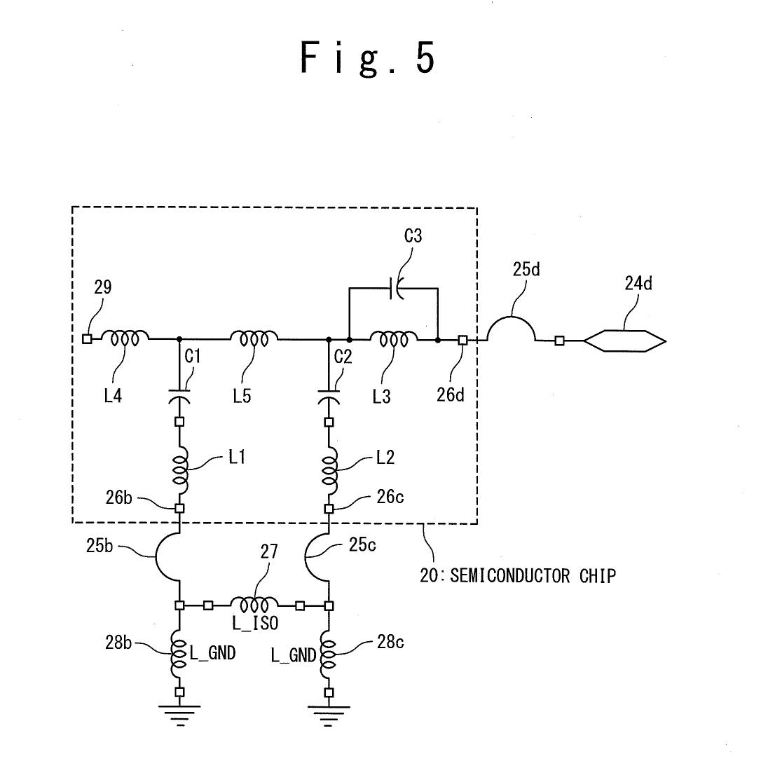

FIG. 5 is an equivalent circuit diagram showing the configuration of the semiconductor device with the filter circuit according to the second embodiment of the present invention in consideration of the parasitic components in the filter circuit.

The difference of the present embodiment of the present invention from the first embodiment is in that a first grounding path through the first capacitance C1, and the bonding pad 26b and the bonding wire 25b. That is, in the semiconductor device with the filter circuit in the first embodiment of the present invention, the first grounding path is configured from the first capacitance C1, and the bonding pad 26b and the bonding wire 25b. However, in the semiconductor device of the present embodiment, the first grounding path is configured from the first capacitance C1, the first inductance L1, and the bonding pad 26b and the bonding wire 25b.

The first grounding path in the present embodiment is designed to configure the first serial resonant circuit and to remove 2f0.

Because the other configuration of the semiconductor device with the filter circuit in the present embodiment is the same as that of the first embodiment of the present invention, the description thereof is omitted.

As shown in FIG. 3, in the signal transmission characteristics of the filter circuit of the present embodiment, the rejection quantity of 2f0 is −51.7 dB in a marker m4 in which a ratio of the parasitic inductances L_GND/L_ISO is 0.08. The rejection quantity increases by 10.1 dB more than in the conventional example.

Although the rejection quantity decreases regardless of addition of the serial resonant circuit for removing 2f0 as compared with the first embodiment, this is because the harmonic frequency component returns to the signal line through the path 27 due to the parasitic inductance. In the table of FIG. 7, comparison of the first embodiment and the present embodiment in the rejection quantity is shown when the parasitic inductance L_ISO of the path 27 is infinite. When L_ISO is infinite, the rejection quantity in the present embodiment increases by 21 dB compared with the first embodiment.

### Third Embodiment

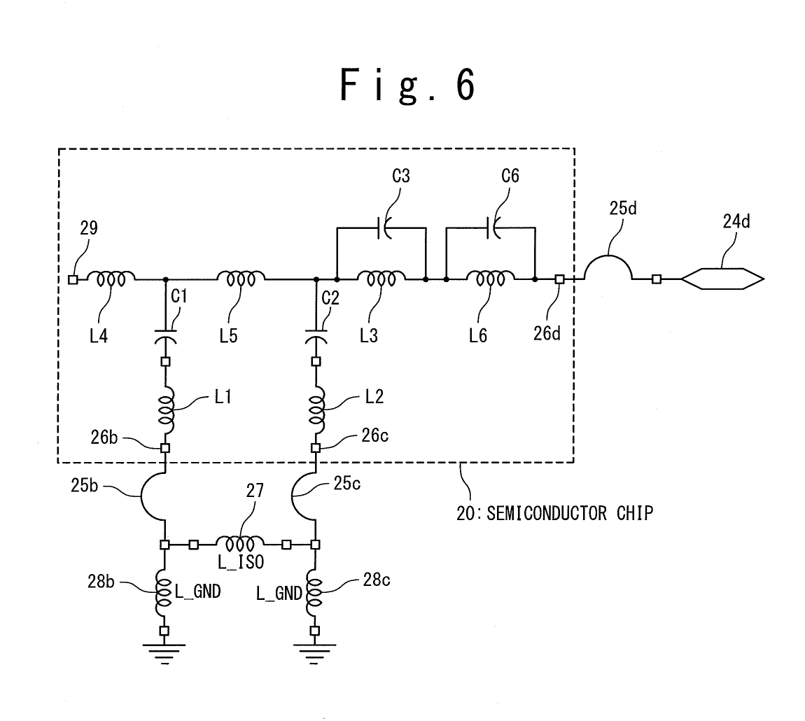

FIG. 6 is an equivalent circuit diagram showing the configuration of the semiconductor device with the filter circuit according to a third embodiment of the present invention.

The difference of the present embodiment of the present invention from the second embodiment is in the parallel resonant circuit section of the filter circuit 21. That is, in the semiconductor device with the filter circuit according to the second embodiment of the present invention, the parallel resonant circuit section is configured from the first parallel resonant circuit by arranging the inductor L3 and the capacitor C3 in parallel. However, in the semiconductor device in the present embodiment, a second parallel resonant circuit of the inductor L6 and the capacitor C6 is arranged in serial to the first parallel resonant circuit.

The first parallel resonant circuit in the present embodiment is designed to block off 2f0 and the second parallel resonant circuit is designed to block off 3f0.

Because the other configuration of the semiconductor device with the filter circuit in the present embodiment is the same as the second embodiment of the present invention, the description thereof is omitted.

As shown in FIG. 3, in the signal transmission characteristics of the filter circuit in the present embodiment, the rejection quantity of 2f0 is −41.8 dB in a marker m5 in which the parasitic inductance ratio L_GND/L_ISO is 0.08. The rejection quantity increases by 10.2 dB more than in the conventional example. Moreover, the rejection quantity is −33.4 dB in a marker m6 for 3f0, and the plurality of harmonic frequency components can be removed.

Although the present invention has been described above in connection with several embodiments thereof, it would be apparent to those skilled in the art that those embodiments are provided solely for illustrating the present invention, and should not be relied upon to construe the appended claims in a limiting sense.

What is claimed is:

1. A filter circuit formed on a semiconductor chip, comprising:
an input node provided to input an input signal;
an output bonding pad provided to output an output signal;
a ground bonding pad provided to be connected a ground through a bonding wire;
a parallel resonant circuit provided between said input node and said output bonding pad and having one end connected to said output bonding pad; and
a serial resonant circuit having one end which is provided between said input node and the other end of said parallel resonant circuit and the other end connected with said ground bonding pad,
wherein said serial resonant circuit comprises a capacitor and an inductor which are connected in serial, and
wherein said parallel resonant circuit comprises a capacitor and an inductor which are connected in parallel.

2. The filter circuit according to claim 1, further comprising:
another ground bonding pad; and
another serial resonant circuit having one end between said input node and said serial resonant circuit and the other end connected with said another ground bonding pad,
wherein said another serial resonant circuit comprises a capacitor and an inductor connected in serial.

3. The filter circuit according to claim 2, further comprising:
an inductor connected between said one end of said serial resonant circuit and said one end of said another serial resonant circuit.

4. The filter circuit according to claim 1, further comprising:
another parallel resonant circuit provided between said one end of said parallel resonant circuit and said output bonding pad,
wherein said another parallel resonant circuit comprises a capacitor and an inductor which are connected in parallel.

5. The filter circuit according to claim 1, wherein said capacitor and said inductor of said serial resonant circuit are set based on a first frequency component which is prevented from being outputted to said output bonding pad, and
wherein said capacitor and said inductor of said parallel resonant circuit are set based on a second frequency component which is prevented from being outputted to said output bonding pad.

6. A semiconductor package comprising:
a semiconductor chip on which a filter circuit is configured;
a mount portion on which said semiconductor chip is mounted and which is designed to be connected with said ground bonding pad through said bonding wire; and
a filter circuit output pin designed to be connected with said output bonding pad through a bonding wire,
wherein said filter circuit comprises:
an input node provided to input an input signal;
an output bonding pad provided to output an output signal;
a ground bonding pad provided to be connected a ground through a bonding wire;
a parallel resonant circuit provided between said input node and said output bonding pad and having one end connected to said output bonding pad; and
a serial resonant circuit having one end which is provided between said input node and the other end of said parallel resonant circuit and the other end connected with said ground bonding pad,
wherein said serial resonant circuit comprises a capacitor and an inductor which are connected in serial, and
wherein said parallel resonant circuit comprises a capacitor and an inductor which are connected in parallel.

7. A semiconductor device comprising:
a mount substrate; and
a semiconductor package designed to be mounted on said mount substrate,
wherein said semiconductor package comprises:
a semiconductor chip on which a filter circuit is configured;
a mount portion on which said semiconductor chip is mounted and which is designed to be connected with said ground bonding pad through said bonding wire; and
a filter circuit output pin designed to be connected with said output bonding pad through a bonding wire,
wherein said filter circuit comprises:
an input node provided to input an input signal;
an output bonding pad provided to output an output signal;
a ground bonding pad provided to be connected a ground through a bonding wire;
a parallel resonant circuit provided between said input node and said output bonding pad and having one end connected to said output bonding pad; and
a serial resonant circuit having one end which is provided between said input node and the other end of said parallel resonant circuit and the other end connected with said ground bonding pad,
wherein said serial resonant circuit comprises a capacitor and an inductor which are connected in serial,
wherein said parallel resonant circuit comprises a capacitor and an inductor which are connected in parallel, and
wherein said mount substrate comprises:
a surface metal ground pattern designed to be connected with said mount portion;
front metal patterns for signals designed to be connected with said filter circuit input node and said filter circuit output pin;
a back metal ground pattern designed to be connected with said surface metal ground pattern; and
a connection section configured to connect said surface metal ground pattern and said back metal ground pattern.

8. The semiconductor device according to claim 7, wherein said connection section comprises through-hole electrodes provided to connect said surface metal ground pattern and said back metal ground pattern.

9. The semiconductor device according to claim 7, wherein said filter circuit further comprises:
another ground bonding pad; and
another serial resonant circuit having one end between said input node and said serial resonant circuit and the other end connected with said another ground bonding pad, and
wherein said another serial resonant circuit comprises a capacitor and an inductor connected in serial.

10. The semiconductor device according to claim 9, wherein said filter circuit further comprises:
an inductor connected between said one end of said serial resonant circuit and said one end of said another serial resonant circuit.

11. The semiconductor device according to claim 7, wherein said filter circuit further comprises:
another parallel resonant circuit provided between said one end of said parallel resonant circuit and said output bonding pad, and
wherein said another parallel resonant circuit comprises a capacitor and an inductor which are connected in parallel.

12. The semiconductor device according to claim 7, wherein said capacitor and said inductor of said serial resonant circuit are set based on a first frequency component which is prevented from being outputted to said output bonding pad, and
wherein said capacitor and said inductor of said parallel resonant circuit are set based on a second frequency component which is prevented from being outputted to said output bonding pad.
